(19) United States
(12) Patent Application Publication
(10) Pub. No.: US 2023/0133798 A1
(43) Pub. Date: May 4, 2023

(54) COOLED EDGE RING WITH INTEGRATED SEALS

(71) Applicant: LAM RESEARCH CORPORATION, Fremont, CA (US)

(72) Inventors: Adam Christopher MACE, Morgan Hil, CA (US); John HOLLAND, San Jose, CA (US); Alexander MATYUSHKIN, San Jose, CA (US); Rajesh DORAI, Pleasanton, CA (US)

(21) Appl. No.: 17/915,558

(22) PCT Filed: Mar. 22, 2021
(86) PCT No.: PCT/US2021/023406

§ 371 Date: Sep. 29, 2022

Related U.S. Application Data
(60) Provisional application No. 63/004,055, filed on Apr. 2, 2020.

(51) Int. Cl. C23C 16/458; C23C 16/46

(52) U.S. Cl. CPC C23C 16/4581; C23C 16/466

(57) ABSTRACT

A substrate support for a substrate processing chamber includes a baseplate, an edge ring arranged on the baseplate, a seal arrangement located between the edge ring and the baseplate that is configured to define an interface between the edge ring and the baseplate, and at least one channel in fluid communication with the interface and configured to supply a heat transfer gas to the interface.

### CROSS-REFERENCE TO RELATED APPLICATIONS

This application claims the benefit of U.S. Provisional Application No. 63/004,055, filed on Apr. 2, 2020. The entire disclosure of the application referenced above is incorporated herein by reference.

### FIELD

The present disclosure relates to controlling edge ring temperature in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, dielectric etch, and/or other etch, deposition, or cleaning processes. A substrate may be arranged on a substrate support, such as a pedestal, an electrostatic chuck (ESC), etc. in a processing chamber of the substrate processing system. During etching, etch gas mixtures including one or more gases may be introduced into the processing chamber and plasma may be used to initiate chemical reactions.

The substrate support may include a ceramic layer arranged to support a substrate. For example, the substrate may be clamped to the ceramic layer during processing. The substrate support may include an edge ring arranged to surround an outer perimeter of the ceramic layer and the substrate.

### SUMMARY

A substrate support for a substrate processing chamber includes a baseplate, an edge ring arranged on the baseplate, a seal arrangement located between the edge ring and the baseplate that is configured to define an interface between the edge ring and the baseplate, and at least one channel in fluid communication with the interface and configured to supply a heat transfer gas to the interface.

In other features, the interface includes a gap between a lower surface of the edge ring and an upper surface of the baseplate. The gap has a depth of less than 25 microns. The seal arrangement includes first and second annular seals and the interface is defined between the first and second annular seals. The seal arrangement includes a third annular seal arranged between the first annular seal and the second annular seal and the third annual seal divides the interface into a first region and a second region. The at least one channel includes a first channel in fluid communication with the first region and a second channel in fluid communication with the second region and the first channel and the second channel are configured to separately receive the heat transfer gas. The seal arrangement includes two or more azimuthal seals extending in a radial direction between the first and second annular seals and the two or more azimuthal seals divide the interface into two or more azimuthal zones configured to separately receive the heat transfer gas.

In other features, the substrate support further includes a support ring configured to bias the edge ring downward toward the interface. The at least one channel is provided through the baseplate. A system includes the substrate support and further includes a heat transfer gas source configured to supply the heat transfer gas to the interface via the at least one channel. A controller is configured to control the supply of the heat transfer gas to the interface to adjust a temperature of the edge ring.

A substrate support for a substrate processing chamber includes a baseplate and an edge ring arranged on the baseplate. A lower surface of the edge ring includes first and second annular grooves. A first seal is arranged in the first annular groove, a second seal is arranged in the second annular groove, the first and second seals define an interface between the edge ring and the baseplate, and the interface is in fluid communication with a heat transfer gas source.

In other features, the substrate support further includes at least one channel in fluid communication with the interface configured to supply a heat transfer gas to the interface from the heat transfer gas source. The first and second seals comprise O-rings. The first and second seals comprise an elastomer material dispensed within the grooves. A system includes the substrate support and further includes the heat transfer gas source. A controller is configured to control a supply of the heat transfer gas to the interface to adjust a temperature of the edge ring.

A substrate support for a substrate processing chamber includes a baseplate, an edge ring arranged on the baseplate, and a gasket arranged on a lower surface of the edge ring between the edge ring and the baseplate. The gasket includes first and second annular rims extending downward toward the baseplate, a plenum is defined between the first and second annular rims, and the plenum is in fluid communication with a heat transfer gas source.

In other features, the substrate support further includes at least one channel in fluid communication with the plenum and configured to supply a heat transfer gas to the plenum from the heat transfer gas source. The gasket is bonded to the lower surface of the edge ring using a thermal adhesive. A system includes the substrate support and further includes the heat transfer gas source. A controller is configured to control a supply of the heat transfer gas to the plenum to adjust a temperature of the edge ring.

A substrate support for a substrate processing chamber includes a baseplate and an edge ring arranged on the baseplate. A plenum is formed in a lower surface of the edge ring between the edge ring and the baseplate, the lower surface of the edge ring includes first and second annular rims extending downward toward the baseplate, the plenum is defined between the first and second annular rims, and the plenum is in fluid communication with a heat transfer gas source.

In other features, the substrate support further includes at least one channel in fluid communication with the plenum and configured to supply a heat transfer gas to the plenum from the heat transfer gas source. A system includes the substrate support and further includes the heat transfer gas source. A controller is configured to control a supply of the heat transfer gas to the plenum to adjust a temperature of the edge ring.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is an example substrate processing system according to the present disclosure;

FIG. 2A is an example substrate support according to the principles of the present disclosure;

FIG. 2B shows a bottom view of an edge ring including example seals defining azimuthal zones according to the principles of the present disclosure; and

FIGS. 3A, 3B, and 3C illustrate example edge rings and seals according to the principles of the present disclosure.

In the drawings, reference numbers may be reused to identify similar and/or identical elements.

### DETAILED DESCRIPTION

In a substrate processing chamber, a temperature of an edge ring affects processing parameters such as etch rate and uniformity at an outer edge of a substrate. The edge ring is exposed to the processing environment (including plasma) and it absorbs heat. Accordingly, the temperature of the edge ring varies during processing and controlling the temperature of the edge ring helps achieve a repeatable etch rate and process uniformity.

In some examples, the edge ring is arranged in thermal contact with a baseplate or lower ring of the substrate support. For example, the baseplate may function as a heat sink for the edge ring and heat is transferred via an interface between the edge ring and the baseplate. In some examples, a thermal interface material (e.g., a silicone-based material such as a gel, paste, pad, etc.) is provided between the edge ring and the baseplate to facilitate transfer of heat from the edge ring to the baseplate. The baseplate may include coolant channels configured to flow coolant and transfer heat out of the baseplate.

Controlling the temperature of the edge ring using direct heat transfer contact between the edge ring and the substrate support or in combination with a thermal interface material provides only passive temperature control. For example, the temperature of the edge ring will vary in accordance with radio frequency (RF) power delivered to the processing chamber, thermal conductivity of the interface and/or interface material, and contact area. Accordingly, heat transfer characteristics (e.g., a heat transfer coefficient) corresponding to heat transfer out of the edge ring cannot be changed without changing hardware or materials such as the thermal interface material.

Further, the thermal interface material (e.g., a silicone gel or paste) is difficult to install, may not have consistent properties in every processing chamber, and/or the properties of the thermal interface material may change over time, contributing to edge ring temperature drift. For example, the thermal interface material may be exposed to process materials (e.g., plasma), further degrading the heat transfer characteristics. Replacing the edge ring requires extensive cleaning of the substrate support to remove the thermal interface material.

Systems and methods according to the present disclosure provide a heat transfer gas (e.g., helium and/or other suitable inert heat transfer gases) to the interface between the edge ring and the baseplate to facilitate temperature control. Pressure of the heat transfer gas may be controlled to adjust heat transfer characteristics during processing. For example, a bottom surface of the edge ring may include a sealing arrangement including an integrated or bonded (i.e., attached) seal configured to contain the heat transfer gas in the interface between the edge ring and the baseplate. The pressure of the heat transfer gas may be adjusted to compensate for differences between processing chambers and/or be adjusted during processing.

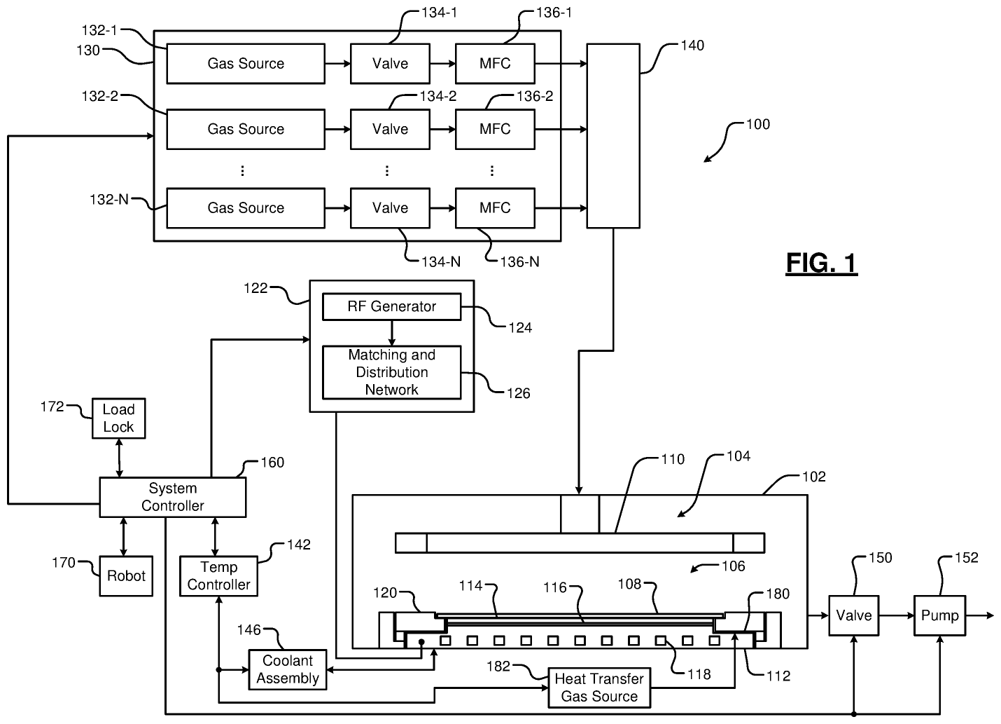

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an ESC. During operation, a substrate 108 is arranged on the substrate support 106. While a specific substrate processing system 100 and processing chamber 102 are shown as an example, the principles of the present disclosure may be applied to other types of substrate processing systems and processing chambers, such as a substrate processing system that generates plasma in-situ, that implements remote plasma generation and delivery (e.g., using a plasma tube, a microwave tube), etc.

For example only, the upper electrode 104 may include a gas distribution device such as a showerhead 110 that introduces and distributes process gases. The showerhead 110 may include a stem portion including one end connected to a top surface of the processing chamber 102. A base portion is generally cylindrical and extends radially outwardly from an opposite end of the stem portion at a location that is spaced from the top surface of the processing chamber. A substrate-facing surface or faceplate of the base portion of the showerhead 110 includes a plurality of holes through which process gas or purge gas flows. Alternately, the upper electrode 104 may include a conducting plate and the process gases may be introduced in another manner.

The substrate support 106 includes a conductive baseplate 112 that acts as a lower electrode. The baseplate 112 supports a ceramic layer 114. A bond layer (e.g., an adhesive and/or thermal bond layer) 116 may be arranged between the ceramic layer 114 and the baseplate 112. The baseplate 112 may include one or more coolant channels 118 for flowing coolant through the baseplate 112. The substrate support 106 may include an edge ring 120 arranged to surround an outer perimeter of the substrate 108.

An RF generating system 122 generates and outputs an RF voltage to one of the upper electrode 104 and the lower electrode (e.g., the baseplate 112 of the substrate support 106). The other one of the upper electrode 104 and the baseplate 112 may be DC grounded, AC grounded or floating. In the present example, the RF voltage is supplied to the lower electrode. For example only, the RF generating system 122 may include an RF voltage generator 124 that generates the RF voltage that is fed by a matching and distribution network 126 to the upper electrode 104 or the baseplate 112. In other examples, the plasma may be generated inductively or remotely. Although, as shown for example purposes, the RF generating system 122 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more etch gases and mixtures thereof. The gas sources may also supply carrier and/or purge gas. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 110.

A temperature controller 142 may communicate with a coolant assembly 146 to control coolant flow through the channels 118. For example, the coolant assembly 146 may include a coolant pump and reservoir. The temperature controller 142 operates the coolant assembly 146 to selectively flow the coolant through the channels 118 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160.

In the substrate support 106 according to the present disclosure, an interface 180 is defined between the edge ring 120 and an upper surface of the baseplate 112. For example, the edge ring 120 may contact and be supported on the upper surface of the baseplate 112. A heat transfer gas such as helium is supplied from a heat transfer gas source 182 to the interface 180. The heat transfer gas facilitates cooling of the edge ring 120 (i.e., heat transfer from the edge ring 120 to baseplate 112. Although shown separately, the heat transfer gas source 182 may be implemented within the gas delivery system 130. The temperature controller 142 (and/or the system controller 160) may be configured to adjust a pressure of the heat transfer gas supplied to the interface 180 to adjust the temperature of the edge ring 120.

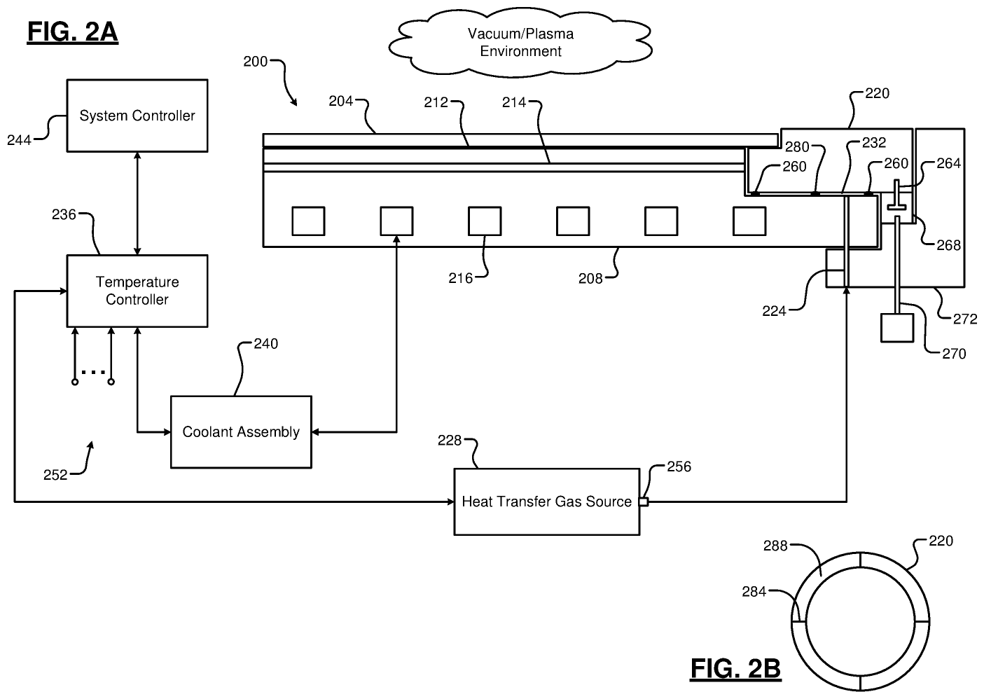

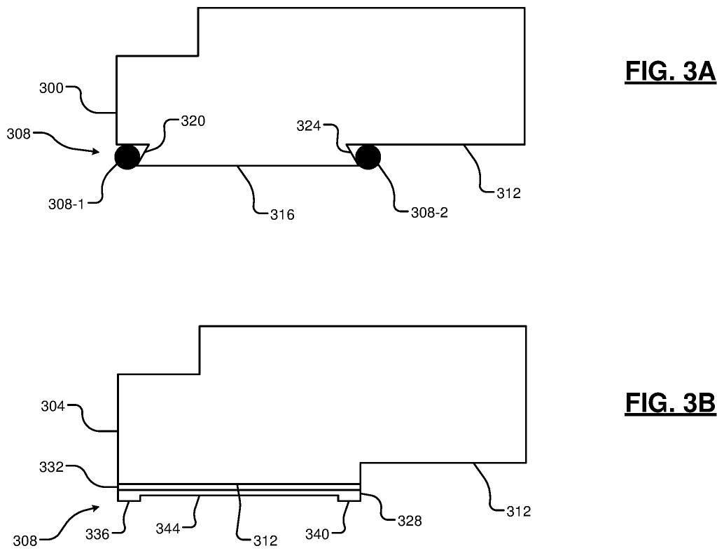

Referring now to FIG. 2A, a portion of an example substrate support 200 according to the present disclosure is shown. The substrate support 200 is configured to support a substrate 204. The substrate support 200 includes a baseplate (e.g., a conductive baseplate) 208, a ceramic layer 212, and, in some examples, a bond layer 214 arranged between the ceramic layer 212 and the baseplate 208. The baseplate 208 may include one or more coolant channels 216 for flowing coolant through the baseplate 208. The substrate support 200 includes an edge ring 220 arranged to surround an outer perimeter of the substrate 204.

The substrate support 200 includes one or more channels 224 (e.g., between one and ten of the channels 224 spaced annularly around the baseplate 208) arranged to provide a heat transfer gas such as helium from a heat transfer gas source 228 to an interface 232 between the edge ring 220 and the baseplate 208 (e.g., to a backside of the edge ring 220). For example, the channels 224 are provided through the baseplate 208 and are in fluid communication with the interface 232. Although the interface 232 is shown with a small gap for example purposes, the edge ring 220 may be supported directly on the upper surface of the baseplate 208. The heat transfer gas facilitates control of the temperature of the edge ring 220.

A temperature controller 236 communicates with a coolant assembly 240 to control coolant flow through the channels 216. The temperature controller 236 communicates with the heat transfer gas source 228 to control flow of the heat transfer gas (e.g., via valves of a gas delivery system such as the gas delivery system 130 described above in FIG. 1). The temperature controller 236 may also operate the coolant assembly 240 to selectively flow the coolant through the channels 216 to cool the substrate support 200. The temperature controller 236 may be a separate controller, implemented within a system controller 244, etc.

The temperature controller 236 may be configured to measure and/or calculate a temperature of the edge ring 220 based in part on sensed and/or modeled temperatures of the substrate support 200 and the edge ring 220, process parameters, etc. For example, the temperature controller 236 determines the temperature of the edge ring 220 in accordance with temperatures of the substrate support 200 and the edge ring 220 as measured using one or more temperature sensors (not shown). In other examples, the temperature controller 236 may be configured to calculate the temperature of the edge ring 220 using other measured and/or estimated values, such as an output of a model. For example, the temperature controller 236 may receive one or more signals 252 corresponding to directly sensed temperatures and/or other process parameters used to calculate the temperature of the edge ring 220.

The temperature controller 236 may determine the flow and/or pressure of the heat transfer gas from one or more sensors 256 arranged between the heat transfer gas source 228 and the substrate support 200. For example, the sensors 256 may correspond to sensors measuring heat transfer gas flow (and/or pressure) provided to the interface 232. The temperature controller 236 is configured to adjust the pressure of the heat transfer gas based on the determined temperature of the edge ring 220 and a desired temperature of the edge ring 220. In other words, the temperature controller 236 may increase or decrease the pressure of the heat transfer gas to decrease or increase the temperature of the edge ring 220 to achieve the desired temperature (e.g., to tune a plasma edge sheath).

In this example, a bottom surface of the edge ring 220 includes a sealing arrangement such as integrated or bonded (i.e., attached) seals 260 configured to contain the heat transfer gas within the interface 232. For example, the seals 260 may be O-rings or other sealing structures comprised of an elastomer or silicone material. In some examples, a bottom surface of the edge ring 220 and/or the upper surface of the baseplate 208 may include one or more recesses or grooves configured to accommodate the seals 260. A distance between the seals 260 may be varied to vary a width of the interface 232. The seals 260 prevent leaking of the heat transfer gas into a processing environment (e.g., a plasma/vacuum environment). Conversely, the seals 260 prevent loss of vacuum in the processing environment.

The edge ring 220 may be biased downward toward the baseplate 208 to compress the seals 260. For example, the edge ring 220 may be biased downward such that the lower surface of the edge ring 220 contacts the upper surface of the baseplate 208 and a consistent gap (e.g., a gap having a depth between 1 and 25 microns) is maintained in both annular and radial directions. Because the heat transfer characteristics are increased with a smaller gap, the gap is minimized to maximize heat transfer out of the edge ring 220 and into the baseplate 208 via the heat transfer gas.

As shown, the edge ring 220 is biased downward using a fastener such as a screw 264 configured to pull the edge ring 220 toward a support ring 268. In some examples, a linear actuator 270 is configured to pull the support ring 268 downward, which in turn pulls the edge ring 220 downward. For example, the support ring 268 may be arranged on an outer ring 272 (e.g., a ring comprising quartz or another insulative material). An outer surface of the linear actuator 270 and inner surfaces of a channel extending through the outer ring 272 and into the support ring 268 may be complementarily thread.

Although the edge ring 220 and the support ring 268 are shown as separate components, in other examples the edge ring 220 and the support ring 268 may comprise a single, integrated component. The downward force exerted on the edge ring 220 opposes upward biasing of the seal 260 and the pressure of the heat transfer gas within the interface 232 and retains the edge ring 220 against the upper surface of the baseplate 208. In other examples, another clamping mechanism may be used. One or more seals (e.g., O-rings; not shown) may be provided as a vacuum break between the support ring 268 and the outer ring 272, between the baseplate 208 and the outer ring 272, etc.

In some examples, another optional seal 280 may be arranged between the seals 260 to divide the interface 232 into two separate regions and respective gaps (i.e., inner and outer annular regions). In this example, the heat transfer gas may be separately provided to the different regions to separately control the heat transfer (and respective temperatures) of different radial regions of the edge ring 220 to compensate for radial non-uniformities. In other examples, additional seals (not shown) may be provided to further divide the interface 232 into multiple, separate regions. In other examples, there are multiple heat transfer gas sources, each in fluid communication with a corresponding region.

In one example, a single heat transfer gas source 228 provides the heat transfer gas to all of the channels 224. In other examples, multiple heat transfer gas sources 228 may be provided to separately supply the heat transfer gas to respective ones of the channels 224. For example, FIG. 2B shows a bottom view of the edge ring 220 in an arrangement where the seals 260 further include a plurality of azimuthal seals 284 extending in a radial direction from an inner to an outer perimeter of the edge ring 220. The seals 284 separate the interface 232 into multiple azimuthal zones 288. The heat transfer gas may be separately provided to the zones 288 via respective ones of the channels 224. In this manner, heat transfer from (and, accordingly, temperature of) the zones 288 may be separately controlled to compensate for azimuthal non-uniformities.

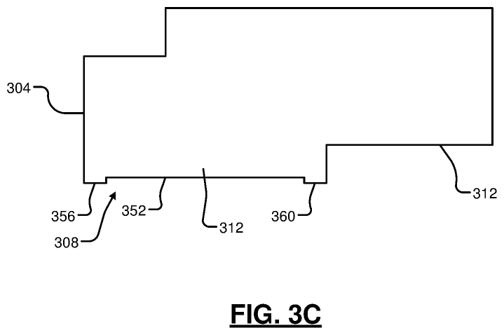

FIGS. 3A and 3B show other example edge rings 300 and 304, respectively, including implementations of a sealing arrangement 308 according to the present disclosure. In FIG. 3A, the sealing arrangement 308 is integrated directly in or on a bottom surface 312 of the edge ring 300. For example, the bottom surface 312 includes a lower portion 316 defining inner and outer grooves 320 and 324 configured to retain respective inner and outer portions 308-1 and 308-2 (e.g., O-rings) of the sealing arrangement 308. The bottom surface 312 on an outer portion (e.g., a shoulder) of the edge ring 300 is substantially flat.

In one example, the inner and outer portions 308-1 and 308-2 of the sealing arrangement 308 are bonded (e.g., using an adhesive) within the grooves 320 and 324. In another example, one or both of the inner and outer portions 308-1 and 308-2 may be retained within the respective grooves 320 and 324 without an adhesive. For example, the outer portion 308-2 of the sealing arrangement 308 may have a slightly smaller diameter than the groove 324 and is stretched for insertion into the groove 324. Conversely, the inner portion 308-1 of the sealing arrangement 308 may have a slightly greater diameter than the groove 320 and is compressed for insertion into the groove. In still another example, the sealing arrangement 308 comprises an elastomer, silicone, epoxy, etc. that is dispensed directly into the grooves 320 and 324.

Accordingly, in the example shown in FIG. 3A, the sealing arrangement 308 can be installed and/or removed when the edge ring 300 is installed or removed without requiring separate installation or removal. Further, in examples where the edge ring 300 is moveable (e.g., for tuning), the sealing arrangement 308 is automatically raised and lowered with the edge ring 300. In these examples, the supply of the heat transfer gas may be stopped when the edge ring 300 is raised.

In the example shown in FIG. 3B, the lower portion 316 is substantially flat and does not include the grooves 320 and 324. Instead, the sealing arrangement 308 corresponds to a gasket 328 comprising a thermal interface material that is directly bonded to the lower portion 316. For example, the gasket 328 is bonded to the lower portion 316 using a thermal adhesive 332. The gasket 328 includes downward-extending inner and outer rims 336 and 340 defining a plenum 344 and the heat transfer gas is supplied to the plenum 344. The rims 336 and 340 are compressed against an upper surface of the baseplate and seal the heat transfer gas within the plenum 344. For example only, the plenum 344 may be etched into a lower surface of the gasket 328 using a laser to achieve a consistent desired depth (e.g., between 1 and 25 microns).

FIG. 3C shows another example edge ring 348 according to the present disclosure. In this example, the sealing arrangement 308 includes a plenum 352 formed in the bottom surface 312 of the edge ring 300 and downward-extending inner and outer rims 356 and 360 define the plenum 352. The heat transfer gas is supplied to the plenum 352. The rims 356 and 360 are compressed against an upper surface of the baseplate and seal the heat transfer gas within the plenum 352 in a manner similar to the example shown in FIG. 3B. For example, lower surfaces of the rims 356 and 360 are smooth (i.e., flat) and, in some examples, may be polished to improve a seal between the edge ring 348 and the upper surface of the baseplate.

For example only, the plenum 352 may be directly etched into the bottom surface 312 of the edge ring 348. For example, the plenum 352 may be etched using a laser (e.g., laser ablation) to achieve a consistent desired depth (e.g., between 1 and 25 microns). In other examples, the edge ring 348 may be machined to form the plenum 352.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing chamber, the substrate support comprising:
a baseplate;
an edge ring arranged on the baseplate;
a seal arrangement located between the edge ring and the baseplate, wherein the seal arrangement is configured to define an interface between the edge ring and the baseplate; and
at least one channel in fluid communication with the interface and configured to supply a heat transfer gas to the interface.

2. The substrate support of claim 1, wherein the interface comprises a gap between a lower surface of the edge ring and an upper surface of the baseplate.

3. The substrate support of claim 2, wherein the gap has a depth of less than 25 microns.

4. The substrate support of claim 1, wherein the seal arrangement includes first and second annular seals and the interface is defined between the first and second annular seals.

5. The substrate support of claim 4, wherein the seal arrangement includes a third annular seal arranged between the first annular seal and the second annular seal, and wherein the third annual seal divides the interface into a first region and a second region.

6. The substrate support of claim 5, wherein the at least one channel includes a first channel in fluid communication with the first region and a second channel in fluid communication with the second region, and wherein the first channel and the second channel are configured to separately receive the heat transfer gas.

7. The substrate support of claim 4, wherein the seal arrangement includes two or more azimuthal seals extending in a radial direction between the first and second annular seals, wherein the two or more azimuthal seals divide the interface into two or more azimuthal zones configured to separately receive the heat transfer gas.

8. The substrate support of claim 1, further comprising a support ring configured to bias the edge ring downward toward the interface.

9. The substrate support of claim 1, wherein the at least one channel is provided through the baseplate.

10. A system comprising the substrate support of claim 1 and further comprising a heat transfer gas source configured to supply the heat transfer gas to the interface via the at least one channel.

11. The system of claim 10, further comprising a controller configured to control the supply of the heat transfer gas to the interface to adjust a temperature of the edge ring.

12. A substrate support for a substrate processing chamber, the substrate support comprising:
a baseplate;
an edge ring arranged on the baseplate, wherein a lower surface of the edge ring includes first and second annular grooves; and
a first seal arranged in the first annular groove; and
a second seal arranged in the second annular groove,
wherein the first and second seals define an interface between the edge ring and the baseplate, wherein the interface is in fluid communication with a heat transfer gas source.

13. The substrate support of claim 12, further comprising at least one channel in fluid communication with the interface and configured to supply a heat transfer gas to the interface from the heat transfer gas source.

14. The substrate support of claim 12, wherein the first and second seals comprise O-rings.

15. The substrate support of claim 12, wherein the first and second seals comprise an elastomer material dispensed within the grooves.

16. A system comprising the substrate support of claim 12 and further comprising the heat transfer gas source.

17. The system of claim 16, further comprising a controller configured to control a supply of the heat transfer gas to the interface to adjust a temperature of the edge ring.

18. A substrate support for a substrate processing chamber, the substrate support comprising:
a baseplate;
an edge ring arranged on the baseplate; and
a gasket arranged on a lower surface of the edge ring between the edge ring and the baseplate, wherein the gasket includes first and second annular rims extending downward toward the baseplate, wherein a plenum is defined between the first and second annular rims, and wherein the plenum is in fluid communication with a heat transfer gas source.

19. The substrate support of claim 18, further comprising at least one channel in fluid communication with the plenum and configured to supply a heat transfer gas to the plenum from the heat transfer gas source.

20. The substrate support of claim 18, wherein the gasket is bonded to the lower surface of the edge ring using a thermal adhesive.

21. A system comprising the substrate support of claim 18 and further comprising the heat transfer gas source.

22. The system of claim 21, further comprising a controller configured to control a supply of the heat transfer gas to the plenum to adjust a temperature of the edge ring.

23. A substrate support for a substrate processing chamber, the substrate support comprising:
a baseplate; and
an edge ring arranged on the baseplate, wherein a plenum is formed in a lower surface of the edge ring between the edge ring and the baseplate, wherein the lower surface of the edge ring includes first and second annular rims extending downward toward the baseplate, wherein the plenum is defined between the first and second annular rims, and wherein the plenum is in fluid communication with a heat transfer gas source.

24. The substrate support of claim 23, further comprising at least one channel in fluid communication with the plenum and configured to supply a heat transfer gas to the plenum from the heat transfer gas source.

25. A system comprising the substrate support of claim 23 and further comprising the heat transfer gas source.

26. The system of claim 25, further comprising a controller configured to control a supply of the heat transfer gas to the plenum to adjust a temperature of the edge ring.
